(19) United States
(12) Patent Application Publication
(10) Pub. No.: US 2026/0286121 A1
(43) Pub. Date: Sep. 24, 2026

(54) RESIN COMPOSITION AND ELECTRONIC COMPONENT DEVICE

(71) Applicant: Resonac Corporation, Tokyo (JP)

(72) Inventors: Yuta SUKEGAWA, Minato-ku, Tokyo (JP); Ayumi NAKAYAMA, Minato-ku, Tokyo (JP); Masashi YAMAURA, Minato-ku, Tokyo (JP)

(73) Assignee: Resonac Corporation, Tokyo (JP)

(21) Appl. No.: 19/479,735

(22) PCT Filed: Jul. 3, 2024
(86) PCT No.: PCT/JP2024/024129

§ 371 Date: Oct. 29, 2025

(30) Foreign Application Priority Data
Jul. 21, 2023 (JP) 2023-119484

(51) Int. Cl. C08L 63/00; C08K 3/04; C08K 3/36; C08K 5/08; C08K 5/3442; C08K 5/5313; C08K 5/5419

(52) U.S. Cl. CPC C08L 63/00; C08K 3/04; C08K 3/36; C08K 5/08; C08K 5/3442; C08K 5/5313; C08K 5/5419; C08K 2201/006; C08L 2203/206; C08L 2205/02

(57) ABSTRACT

A resin composition contains an epoxy resin, an active ester compound as a curing agent, an inorganic filler containing silica, and a cyclic carbodiimide compound.

### TECHNICAL FIELD

The disclosure relates to a resin composition and an electronic component device.

### RELATED ART

The amount of transmission loss generated by thermal conversion of radio waves transmitted for communication in a dielectric is expressed as the product of frequency, the square root of relative permittivity, and dielectric loss tangent. In other words, since transmission signals are more likely to convert to heat in proportion to frequency, low dielectric properties are required for communication member materials in higher frequency bands in order to suppress transmission loss.

For example, Patent Documents 1-2 disclose thermosetting resin compositions containing active ester resins as curing agents, and it is stated that the dielectric loss tangent of cured products may be kept low.

In the information and communication field, radio waves are becoming higher in frequency with the increase in the number of channels and the amount of information transmitted. Currently, studies on fifth-generation mobile communication systems are being conducted worldwide, and several candidates in the range of approximately 30 GHz to 70 GHz are raised for the frequency bands to be used. Since wireless communication will mainly use such high frequency bands in the future, even lower dielectric loss tangent is required for communication member materials.

### CITATION LIST

### Patent Literature

Patent Document 1: Japanese Patent Application Laid-Open Publication No. 2012-246367
Patent Document 2: Japanese Patent Application Laid-Open Publication No. 2014-114352

### SUMMARY OF INVENTION

### Technical Problem

As in the above-mentioned Patent Documents 1-2, it became clear that using active ester resins as curing agents reduces the dielectric loss tangent of cured products, but decreases crosslink density and reduces strength.

The disclosure has an object to provide a resin composition that has a low dielectric loss tangent and excellent strength when formed into a cured product, and an electronic component device using the same.

### Solution to Problem

Specific means for solving the above problem include the following aspects.
<1> A resin composition that contains an epoxy resin, an active ester compound as a curing agent, an inorganic filler containing silica, and a cyclic carbodiimide compound.
<2> The resin composition according to <1>, in which the content of the cyclic carbodiimide compound is 1 part by mass or more with respect to 100 parts by mass of the epoxy resin.
<3> The resin composition according to <1> or <2>, in which the content of the cyclic carbodiimide compound is 50 parts by mass or less with respect to 100 parts by mass of the epoxy resin.
<4> The resin composition according to any one of <1> to <3>, in which a ratio of a total amount of a functional group equivalent number of the entire curing agent and an imide group equivalent number of the cyclic carbodiimide compound to an epoxy group equivalent number of the epoxy resin [(functional group equivalent number of entire curing agent+imide group equivalent number of carbodiimide group)/epoxy group equivalent number of epoxy resin] is 0.51 to 2.20.
<5> The resin composition according to any one of <1> to <4>, which further contains at least one selected from a group consisting of a curing accelerator, a coupling agent, an ion exchanger, a release agent, a flame retardant, a colorant, and a stress relaxation agent.
<6> An electronic component device, which includes:
a support member;
an electronic component disposed on the support member;
a cured product of the resin composition according to any one of <1> to <5> that seals the electronic component.

### Effects of Invention

According to the disclosure, a resin composition that has a low dielectric loss tangent and excellent strength when formed into a cured product, and an electronic component device using the same are provided.

### DESCRIPTION OF THE EMBODIMENTS

In the disclosure, the term “step” includes not only steps that are independent from other steps, but also steps that cannot be clearly distinguished from other steps, as long as the purpose of the step is achieved.

In the disclosure, numerical ranges indicated using “~” include the numerical values described before and after “~” as the minimum value and maximum value, respectively.

In numerical ranges described stepwise in the disclosure, an upper limit or lower limit described in one numerical range may be replaced with an upper limit or lower limit of another stepwise numerical range. Also, in numerical ranges described in the disclosure, the upper limit or lower limit of the numerical range may be replaced with values shown in the Examples.

In the disclosure, each component may contain multiple types of corresponding substances. In the case of multiple types of substances corresponding to each component existing in the composition, the content ratio or content of each component means the total content ratio or content of the multiple types of substances existing in the composition, unless otherwise specified.

In the disclosure, particles corresponding to each component may contain multiple types. In the case of multiple types of particles corresponding to each component existing in the composition, the particle diameter of each component means the value for the mixture of the multiple types of particles existing in the composition, unless otherwise specified.

Hereinafter, modes for carrying out the disclosure will be described in detail. However, the disclosure is not limited to the following embodiments. In the following embodiments, the constituent elements (including element steps and the like) are not essential unless specifically indicated. The same applies to numerical values and ranges thereof, which do not limit the disclosure.

### <Resin Composition>

A resin composition according to one embodiment of the disclosure contains an epoxy resin, an active ester compound as a curing agent, an inorganic filler containing silica, and a cyclic carbodiimide compound.

In the case of the above configuration, the reason why the cured product has a low dielectric loss tangent and excellent strength is not clear, but is presumed as follows.

In the resin composition of the disclosure, since an active ester compound is used, the dielectric loss tangent of the cured product becomes low. However, in the cured product of the epoxy resin and the active ester compound, the crosslink density becomes small and the strength decreases.

Therefore, the resin composition of the disclosure contains a cyclic carbodiimide compound. Since secondary hydroxyl groups are not generated in the curing reaction between the epoxy resin and the active ester compound, it is considered that the cyclic carbodiimide compound does not react and is presumed not to contribute to the strength of the cured product. However, in reality, the strength of the cured product is improved. The reason for this is presumed to be that not only the curing reaction between the epoxy resin and the active ester compound proceeds, but also self-polymerization between epoxy resins progresses, secondary hydroxyl groups are generated by this self-polymerization, and the cyclic carbodiimide compound reacts with these secondary hydroxyl groups. In particular, since the carbodiimide compound contains a cyclic structure, the strength of the cured product is enhanced.

Furthermore, it was also found that the inclusion of a cyclic carbodiimide compound further reduced the dielectric loss tangent of the cured product. This is thought to be because secondary hydroxyl groups generated by self-polymerization of the epoxy resin are consumed in the reaction with the cyclic carbodiimide compound, further reducing the hydroxyl groups that contribute to an increase in the dielectric loss tangent.

### (Epoxy Resin)

The type of epoxy resin is not particularly limited as long as it has an epoxy group in the molecule.

Specific examples of the epoxy resin include novolac-type epoxy resins (phenol novolac-type epoxy resins, orthocresol novolac-type epoxy resins, etc.) which are epoxidized novolac resins obtained by condensing or co-condensing at least one phenolic compound selected from the group consisting of phenolic compounds such as phenol, cresol, xylenol, resorcinol, catechol, bisphenol A, and bisphenol F, and naphthol compounds such as α-naphthol, β-naphthol, and dihydroxynaphthalene, with aliphatic aldehyde compounds such as formaldehyde, acetaldehyde, and propionaldehyde under acidic catalyst; triphenylmethane-type epoxy resins which are epoxidized triphenylmethane-type phenolic resins obtained by condensing or co-condensing the above phenolic compounds with aromatic aldehyde compounds such as benzaldehyde and salicylaldehyde under acidic catalyst; copolymer-type epoxy resins which are epoxidized novolac resins obtained by co-condensing the above phenolic compounds and naphthol compounds with aldehyde compounds under acidic catalyst; diphenylmethane-type epoxy resins which are diglycidyl ethers of bisphenol A, bisphenol F, etc.; biphenyl-type epoxy resins which are diglycidyl ethers of alkyl-substituted or unsubstituted biphenols; biphenyl skeleton-type epoxy resins such as biphenyl aralkyl-type epoxy resins; stilbene-type epoxy resins which are diglycidyl ethers of stilbene-based phenolic compounds; sulfur atom-containing epoxy resins which are diglycidyl ethers of bisphenol S, etc.; epoxy resins which are glycidyl ethers of alcohols such as butanediol, polyethylene glycol, and polypropylene glycol; glycidyl ester-type epoxy resins which are glycidyl esters of polyvalent carboxylic acid compounds such as phthalic acid, isophthalic acid, and tetrahydrophthalic acid; glycidyl amine-type epoxy resins in which active hydrogen bonded to nitrogen atoms of aniline, diaminodiphenylmethane, isocyanuric acid, etc. is substituted with glycidyl groups; dicyclopentadiene-type epoxy resins which are epoxidized co-condensation resins of dicyclopentadiene and phenolic compounds; alicyclic epoxy resins such as vinylcyclohexene diepoxide, 3,4-epoxycyclohexylmethyl-3,4-epoxycyclohexanecarboxylate, and 2-(3,4-epoxy)cyclohexyl-5,5-spiro(3,4-epoxy)cyclohexane-m-dioxane, which are obtained by epoxidizing olefin bonds in the molecule; paraxylylene-modified epoxy resins which are glycidyl ethers of paraxylylene-modified phenolic resins; metaxylylene-modified epoxy resins which are glycidyl ethers of metaxylylene-modified phenolic resins; terpene-modified epoxy resins which are glycidyl ethers of terpene-modified phenolic resins; dicyclopentadiene-modified epoxy resins which are glycidyl ethers of dicyclopentadiene-modified phenolic resins; cyclopentadiene-modified epoxy resins which are glycidyl ethers of cyclopentadiene-modified phenolic resins; polycyclic aromatic ring-modified epoxy resins which are glycidyl ethers of polycyclic aromatic ring-modified phenolic resins; naphthalene-type epoxy resins which are glycidyl ethers of naphthalene ring-containing phenolic resins; halogenated phenol novolac-type epoxy resins; hydroquinone-type epoxy resins; trimethylolpropane-type epoxy resins; linear aliphatic epoxy resins obtained by oxidizing olefin bonds with peracids such as peracetic acid; aralkyl-type epoxy resins which are epoxidized aralkyl-type phenolic resins such as phenol aralkyl resins and naphthol aralkyl resins; and the like. Furthermore, epoxidized products of acrylic resins and the like may also be raised as epoxy resins. These epoxy resins may be used singly or in combination of two or more.

The epoxy equivalent (molecular weight/number of epoxy groups) of the epoxy resin is not particularly limited. From the viewpoint of balance of various properties such as moldability, reflow resistance, and electrical reliability, the epoxy equivalent of the epoxy resin is preferably 100 g/eq to 1000 g/eq, and more preferably 150 g/eq to 500 g/eq.

The epoxy equivalent of the epoxy resin shall be a value measured by a method according to JIS K 7236:2009.

In the case of the epoxy resin being solid, the softening point or melting point of the epoxy resin is not particularly limited. The softening point or melting point of the epoxy resin is preferably 40° C. to 180° C. from the viewpoint of moldability and reflow resistance, and more preferably 50° C. to 130° C. from the viewpoint of handleability during preparation of the resin composition.

The melting point or softening point of the epoxy resin shall be a value measured by differential scanning calorimetry (DSC) or a method according to JIS K 7234:1986 (ring and ball method).

The mass ratio of the epoxy resin to the total amount of the resin composition is preferably 0.5% by mass to 30% by mass from the viewpoint of strength, fluidity, heat resistance, moldability, etc., more preferably 2% by mass to 20% by mass, and even more preferably 3.5% by mass to 13% by mass.

### (Curing Agent)

The resin composition includes an active ester compound as a curing agent. The active ester compound may be used alone or in combination of two or more.

Here, the active ester compound refers to a compound that has one or more ester groups that react with epoxy groups in one molecule and has a curing action on epoxy resin.

In the case of using an active ester compound, the dielectric loss tangent of the cured product can be suppressed to a low level compared to the case of using a phenolic curing agent or amine curing agent as the curing agent. The reason is presumed as follows.

In the reaction between epoxy resin and phenolic curing agent or amine curing agent, secondary hydroxyl groups are generated. In contrast, in the reaction between epoxy resin and active ester compound, ester groups are generated instead of secondary hydroxyl groups. Since ester groups have lower polarity compared to secondary hydroxyl groups, a resin composition containing an active ester compound as a curing agent can suppress the dielectric loss tangent of the cured product to a low level compared to a resin composition containing only a curing agent that generates secondary hydroxyl groups as the curing agent.

Also, since polar groups in the cured product enhance the water absorption of the cured product, by using an active ester compound as the curing agent, the polar group concentration of the cured product can be suppressed, and the water absorption of the cured product can be suppressed. By suppressing the water absorption of the cured product, that is, by suppressing the content of H₂O which is a polar molecule, the dielectric loss tangent of the cured product can be suppressed to an even lower level.

The type of active ester compound is not particularly limited as long as it is a compound having one or more ester groups that react with epoxy groups in the molecule. Examples of active ester compounds include phenol ester compounds, thiophenol ester compounds, N-hydroxyamine ester compounds, esterified products of heterocyclic hydroxy compounds, and the like.

Examples of active ester compounds include ester compounds obtained from at least one of aliphatic carboxylic acids and aromatic carboxylic acids and at least one of aliphatic hydroxy compounds and aromatic hydroxy compounds. Ester compounds having aliphatic compounds as polycondensation components tend to have excellent compatibility with epoxy resins by having aliphatic chains. Ester compounds having aromatic compounds as polycondensation components tend to have excellent heat resistance by having aromatic rings.

Specific examples of active ester compounds include aromatic esters obtained by condensation reaction between aromatic carboxylic acids and phenolic hydroxyl groups. Among these, aromatic esters are preferred which are obtained by the condensation reaction of an aromatic carboxylic acid with a phenolic hydroxyl group using a mixture of raw materials: an aromatic carboxylic acid component in which two to four hydrogen atoms on the aromatic ring of benzene, naphthalene, biphenyl, diphenylpropane, diphenylmethane, diphenyl ether, diphenylsulfonic acid, etc. are substituted with carboxy groups; a monohydric phenol in which one hydrogen atom on the aromatic ring is substituted with a hydroxyl group; and a polyhydric phenol in which two to four hydrogen atoms on the aromatic ring are substituted with hydroxyl groups. That is, aromatic esters having structural units derived from the aromatic carboxylic acid components, structural units derived from the monohydric phenols, and structural units derived from the polyhydric phenols are preferred.

Specific examples of active ester compounds include active ester resins having a structure obtained by reacting a phenolic resin having a molecular structure in which phenolic compounds are linked via aliphatic cyclic hydrocarbon groups, aromatic dicarboxylic acids or halides thereof, and aromatic monohydroxy compounds, as described in Japanese Patent Application Laid-Open Publication No. 2012-246367. As the active ester resin, compounds represented by the following structural formula (1) are preferred.

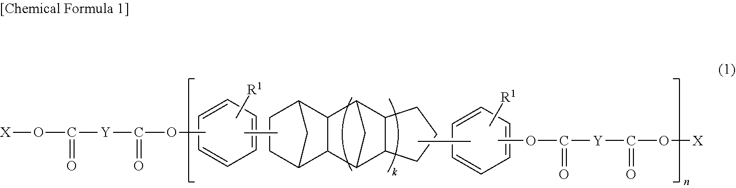

In structural formula (1), R¹ is an alkyl group having 1 to 4 carbon atoms, X is an unsubstituted benzene ring, an unsubstituted naphthalene ring, a benzene ring or naphthalene ring substituted with an alkyl group having 1 to 4 carbon atoms, or a biphenyl group, Y is a benzene ring, a naphthalene ring, or a benzene ring or naphthalene ring substituted with an alkyl group having 1 to 4 carbon atoms, k is 0 or 1, and n represents the average number of repetitions and is 0.25 to 1.5.

Specific examples of compounds represented by structural formula (1) include, for example, the following exemplified compounds (1-1) to (1-10). t-Bu in the structural formulas is a tert-butyl group.

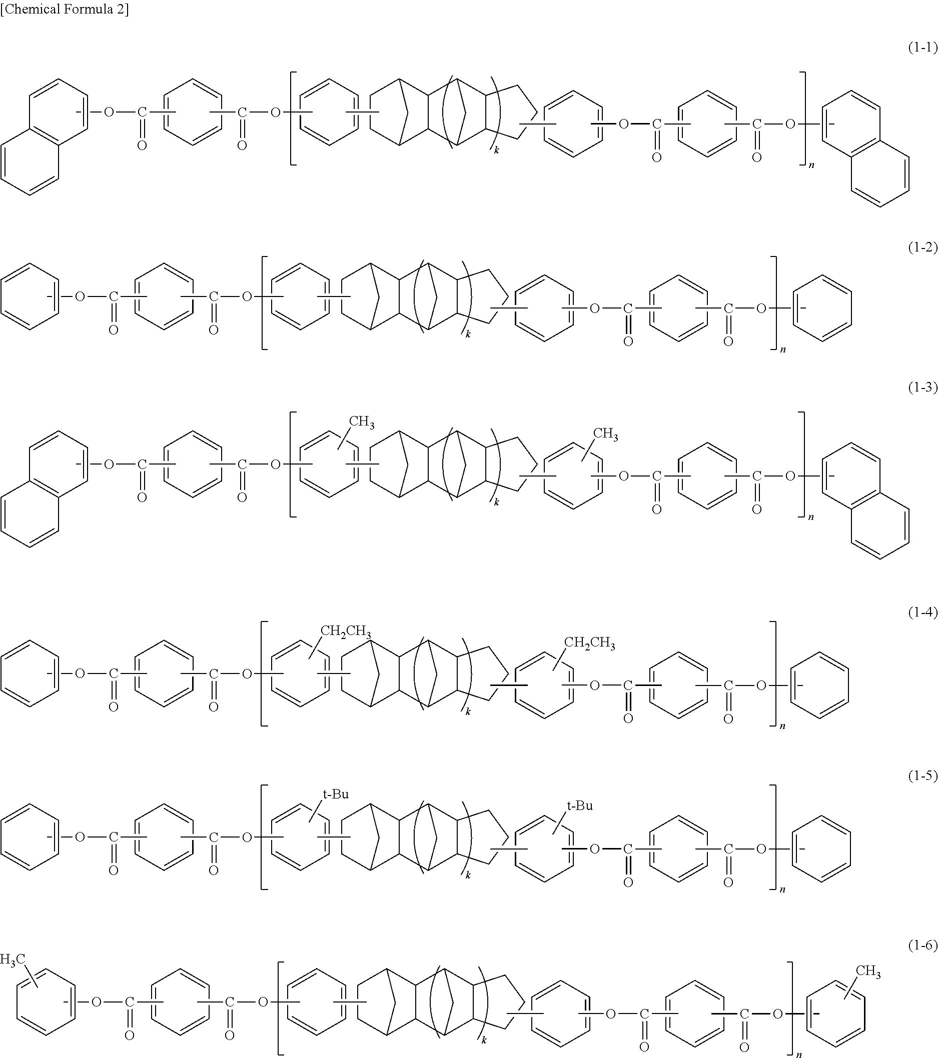

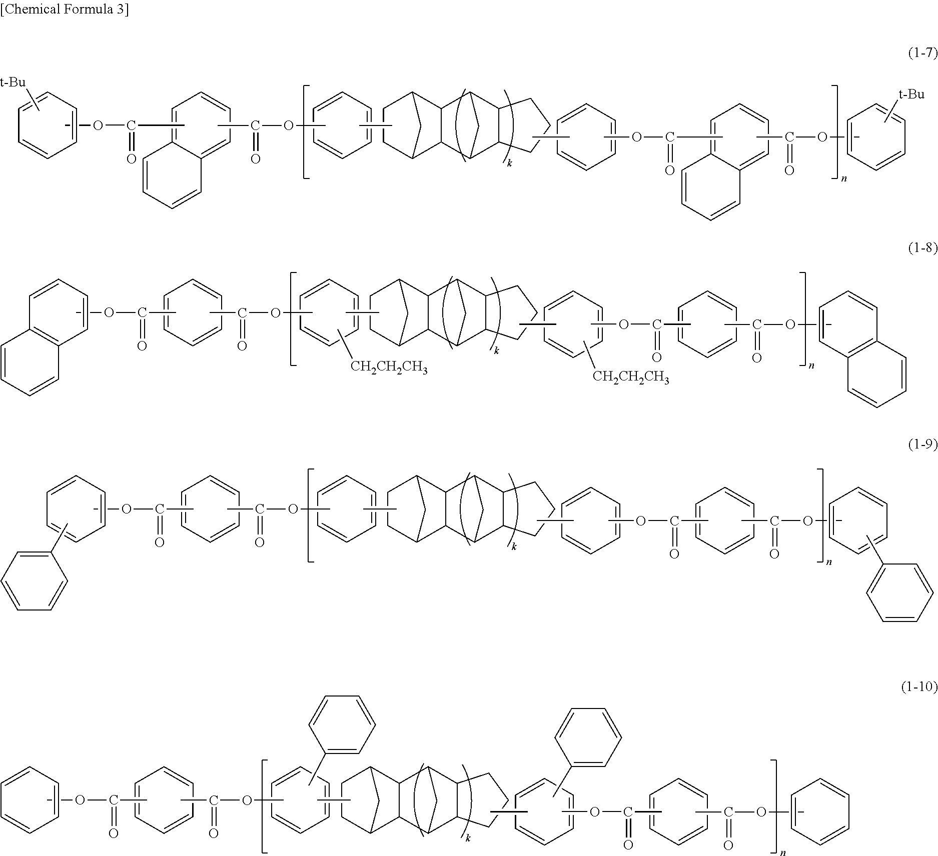

Other specific examples of active ester compounds include compounds represented by the following structural formula (2) and compounds represented by the following structural formula (3), as described in Japanese Patent Application Laid-Open Publication No. 2014-114352.

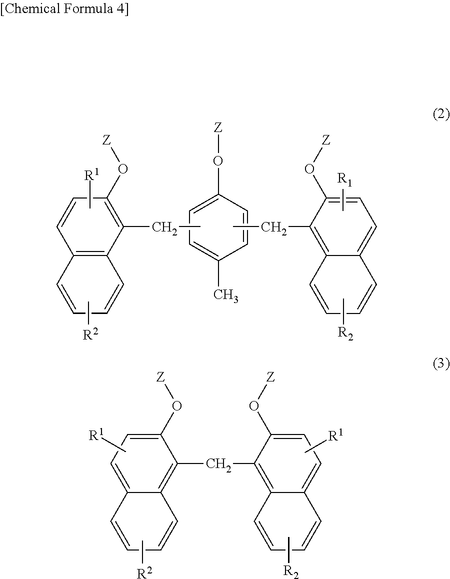

In structural formula (2), R¹ and R² are each independently a hydrogen atom, an alkyl group having 1 to 4 carbon atoms, or an alkoxy group having 1 to 4 carbon atoms, and Z is an ester-forming structural moiety (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2), and at least one of Z is an ester-forming structural moiety (z1).

In structural formula (3), R¹ and R² are each independently a hydrogen atom, an alkyl group having 1 to 4 carbon atoms, or an alkoxy group having 1 to 4 carbon atoms, and Z is an ester-forming structural moiety (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2), and at least one of Z is an ester-forming structural moiety (z1).

Specific examples of compounds represented by structural formula (2) include, for example, the following exemplified compounds (2-1) to (2-6).

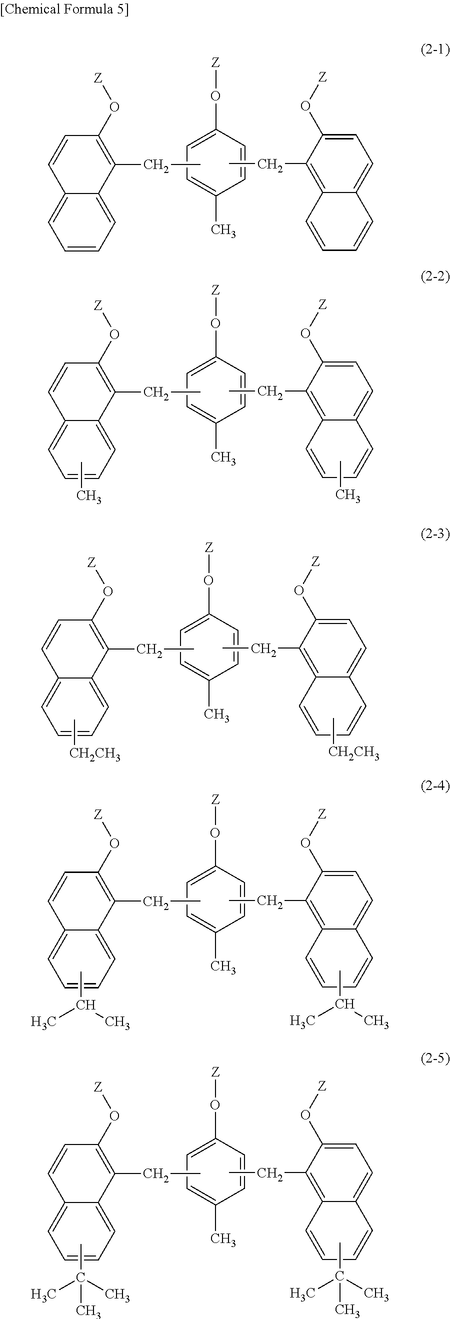

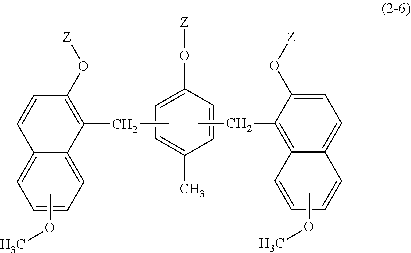

Specific examples of compounds represented by structural formula (3) include, for example, the following exemplified compounds (3-1) to (3-6).

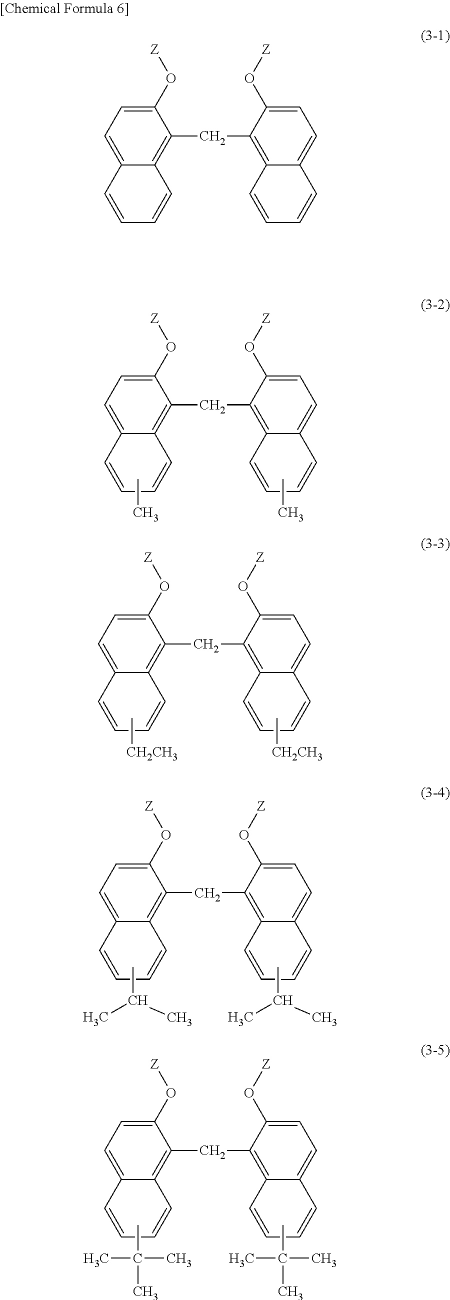

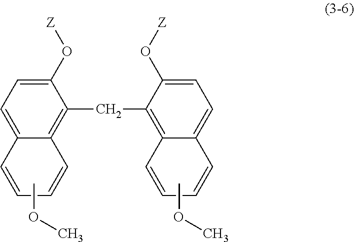

Commercially available products may be used as the active ester compound. Examples of commercially available active ester compounds include “EXB9451”, “EXB9460”, “EXB9460S”, and “HPC-8000-65T” (manufactured by DIC Corporation) as active ester compounds containing a dicyclopentadiene-type diphenol structure; “EXB9416-70BK”, “EXB-8”, and “EXB-9425” (manufactured by DIC Corporation) as active ester compounds containing an aromatic structure; “DC808” (manufactured by Mitsubishi Chemical Corporation) as an active ester compound containing an acetylated product of phenol novolac; and “YLH1026” (manufactured by Mitsubishi Chemical Corporation) as an active ester compound containing a benzoylated product of phenol novolac.

The ester equivalent (molecular weight/number of ester groups) of the active ester compound is not particularly limited. From the viewpoint of balance of various properties such as moldability, reflow resistance, and electrical reliability, 150 g/eq to 400 g/eq is preferable, 170 g/eq to 300 g/eq is more preferable, and 200 g/eq to 250 g/eq is further preferable.

The ester equivalent of the active ester compound is a value measured by a method according to JIS K 0070:1992.

The equivalent number ratio of epoxy resin to active ester compound (ester group/epoxy group) is preferably 0.9 or more, more preferably 0.95 or more, and further preferably 0.97 or more from the viewpoint of suppressing the dielectric loss tangent of the cured product to a low level.

The equivalent number ratio of epoxy resin to active ester compound (ester group/epoxy group) is preferably 1.1 or less, more preferably 1.05 or less, and further preferably 1.03 or less from the viewpoint of suppressing the unreacted portion of the active ester compound to a low level.

The resin composition may contain other curing agents besides the active ester compound.

The type of other curing agents is not particularly limited and may be selected according to the desired properties of the resin composition. Examples of other curing agents include phenolic curing agents, amine curing agents, acid anhydride curing agents, polymercaptan curing agents, polyaminoamide curing agents, isocyanate curing agents, blocked isocyanate curing agents, and the like.

The other curing agents may be used singly or in combination of two or more.

Specific examples of phenolic curing agents include polyhydric phenolic compounds such as resorcinol, catechol, bisphenol A, bisphenol F, and substituted or unsubstituted biphenol; novolac-type phenolic resins obtained by condensing or co-condensing at least one phenolic compound selected from the group consisting of phenolic compounds such as phenol, cresol, xylenol, resorcinol, catechol, bisphenol A, bisphenol F, phenylphenol, and aminophenol, and naphthol compounds such as α-naphthol, β-naphthol, and dihydroxynaphthalene, with aldehyde compounds such as formaldehyde, acetaldehyde, and propionaldehyde under acidic catalyst; aralkyl-type phenolic resins such as phenol aralkyl resins and naphthol aralkyl resins synthesized from the above phenolic compounds and dimethoxyparaxylene, bis(methoxymethyl)biphenyl, and the like; paraxylylene-modified phenolic resins and metaxylylene-modified phenolic resins; melamine-modified phenolic resins; terpene-modified phenolic resins; dicyclopentadiene-type phenolic resins and dicyclopentadiene-type naphthol resins synthesized by copolymerization from the above phenolic compounds and dicyclopentadiene; cyclopentadiene-modified phenolic resins; polycyclic aromatic ring-modified phenolic resins; biphenyl-type phenolic resins; triphenylmethane-type phenolic resins obtained by condensing or co-condensing the above phenolic compounds with aromatic aldehyde compounds such as benzaldehyde and salicylaldehyde under acidic catalyst; and phenolic resins obtained by copolymerizing two or more of these. These phenolic curing agents may be used singly or in combination of two or more.

The functional group equivalent of other curing agents (hydroxyl group equivalent in the case of phenolic curing agents) is not particularly limited. From the viewpoint of balance of various properties such as moldability, reflow resistance, and electrical reliability, the functional group equivalent of other curing agents is preferably 70 g/eq to 1000 g/eq, and more preferably 80 g/eq to 500 g/eq.

The functional group equivalent of other curing agents (hydroxyl group equivalent in the case of phenolic curing agents) shall be the value measured by a method conforming to JIS K 0070:1992.

The softening point or melting point of the curing agent is not particularly limited. The softening point or melting point of the curing agent is preferably 40° C. to 180° C. from the viewpoint of moldability and reflow resistance, and more preferably 50° C. to 130° C. from the viewpoint of handleability during production of the resin composition.

The melting point or softening point of the curing agent is a value measured in the same manner as the melting point or softening point of the epoxy resin.

The equivalent number ratio between the epoxy resin and the curing agent (all curing agents in the case of using multiple types of curing agents), that is, the ratio of the number of functional groups in the curing agent to the number of functional groups in the epoxy resin (number of functional groups in the curing agent/number of functional groups in the epoxy resin), is not particularly limited. From the viewpoint of suppressing unreacted components, it is preferably set in the range of 0.5 to 2.0, and more preferably set in the range of 0.6 to 1.3. From the viewpoint of moldability and reflow resistance, it is further preferably set in the range of 0.8 to 1.2.

The mass ratio of the active ester compound in the total amount of the active ester compound and other curing agents is preferably 80% by mass or more, more preferably 85% by mass or more, and further preferably 90% by mass or more from the viewpoint of suppressing the dielectric loss tangent of the cured product to a low level.

The total mass ratio of the epoxy resin and the active ester compound in the total amount of the epoxy resin and the curing agent is preferably 80% by mass or more, more preferably 85% by mass or more, and further preferably 90% by mass or more from the viewpoint of suppressing the dielectric loss tangent of the cured product to a low level.

### (Cyclic Carbodiimide Compound)

The cyclic carbodiimide compound is a compound having one or more carbodiimide groups (—N═C═N—) in the molecule and having a cyclic structure in which two nitrogen atoms constituting the carbodiimide group are bonded by a linking group. The cyclic carbodiimide compound may be used alone or in combination of two or more types.

From the viewpoint of improving the strength of the resin composition as a cured product, the cyclic carbodiimide compound preferably contains two or more carbodiimide groups in the molecule.

The cyclic structure in the cyclic carbodiimide compound may be one or two or more. In the case of having two or more cyclic structures, two rings may share two or more atoms as in bicyclo structures, tricyclo structures, etc., or one atom may be shared in two rings as in spiro structures. Furthermore, a structure having two or more cyclic structures may be formed by atoms constituting the cyclic structure having a cyclic group as a substituent.

Examples of the cyclic carbodiimide compound include compounds represented by the following general formula (1).

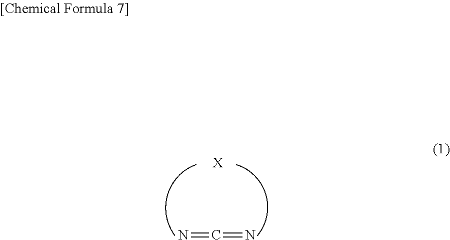

In general formula (1), X is a divalent or higher linking group. In the case of X being a trivalent or higher linking group, it may be bonded to a polymer or bonded to other cyclic structures.

The linking group represented by X contains carbon atoms and hydrogen atoms, and may further contain heteroatoms. Examples of the heteroatoms include oxygen atoms, nitrogen atoms, sulfur atoms, phosphorus atoms, and the like.

The number of atoms (ring members) in the cyclic structure composed of the carbodiimide group and X is not particularly limited, and is preferably 8 to 50, more preferably 10 to 30, and even more preferably 10 to 20. The number of ring members here does not include the number of atoms in substituents.

Specific examples of the linking group represented by X include aliphatic hydrocarbon groups, alicyclic hydrocarbon groups, aromatic hydrocarbon groups, combinations thereof, or combinations of these with heteroatoms.

Examples of the aliphatic hydrocarbon group represented by X include alkylene groups having 1 to 20 carbon atoms, alkanetriyl groups having 1 to 20 carbon atoms, alkanetetrayl groups having 1 to 20 carbon atoms, and the like. The aliphatic hydrocarbon group may have substituents. Examples of the substituents include aryl groups having 6 to 15 carbon atoms, halogen atoms, nitro groups, amide groups, hydroxyl groups, ester groups, ether groups, aldehyde groups, and the like.

Examples of the alicyclic hydrocarbon group represented by X include cycloalkylene groups having 3 to 20 carbon atoms, cycloalkanetriyl groups having 3 to 20 carbon atoms, and cycloalkanetetrayl groups having 3 to 20 carbon atoms. The alicyclic hydrocarbon group may have substituents. Examples of the substituents include alkyl groups having 1 to 20 carbon atoms, aryl groups having 6 to 15 carbon atoms, halogen atoms, nitro groups, amide groups, hydroxyl groups, ester groups, ether groups, aldehyde groups, and the like.

Examples of the aromatic hydrocarbon group include arylene groups having 5 to 15 carbon atoms, arenetriyl groups having 5 to 15 carbon atoms, and arenetetrayl groups having 5 to 15 carbon atoms. The aromatic hydrocarbon group may have substituents. Examples of the substituents include alkyl groups having 1 to 20 carbon atoms, aryl groups having 6 to 15 carbon atoms, halogen atoms, nitro groups, amide groups, hydroxyl groups, ester groups, ether groups, aldehyde groups, and the like.

The molecular weight of the cyclic carbodiimide compound is preferably 100 to 3,000, more preferably 100 to 2,500, and even more preferably 250 to 2,500.

The imide equivalent of the cyclic carbodiimide compound is preferably 25 to 500, more preferably 25 to 325, and even more preferably 62 to 325.

The cyclic carbodiimide compound may be solid or liquid at room temperature (25° C.). In the case of the cyclic carbodiimide compound being solid, the shape thereof may be any shape, and may be particulate.

In the case of the cyclic carbodiimide compound being particulate, the average particle diameter of the particles is preferably 200 μm or less, more preferably 100 μm or less, even more preferably 20 μm or less, particularly preferably 10 μm or less, and extremely preferably 8 μm or less.

Also, the average particle diameter of the cyclic carbodiimide compound is preferably 0.1 μm or more, more preferably 0.5 μm or more, and even more preferably 0.8 μm or more.

In the disclosure, the average particle diameter of the cyclic carbodiimide compound means the volume average particle diameter. Specifically, it means the particle diameter (D50) at which the cumulative distribution from the small diameter side becomes 50% in a volume-based particle size distribution curve obtained by laser diffraction scattering method.

In the case of the cyclic carbodiimide compound being particulate, the maximum particle diameter (Dmax) of the particles is preferably 2 mm or less, more preferably 800 μm or less, even more preferably 100 μm or less, and particularly preferably 50 μm or less.

Also, the maximum particle diameter (Dmax) of the cyclic carbodiimide compound is preferably 1 μm or more, more preferably 3 μm or more, and even more preferably 5 μm or more.

In the disclosure, the maximum particle diameter (Dmax) of the cyclic carbodiimide compound means the maximum particle diameter in a volume-based particle size distribution curve obtained by laser diffraction scattering method.

In the case of the cyclic carbodiimide compound having a spiro structure, examples of the cyclic carbodiimide compound include compounds represented by the following general formula (2).

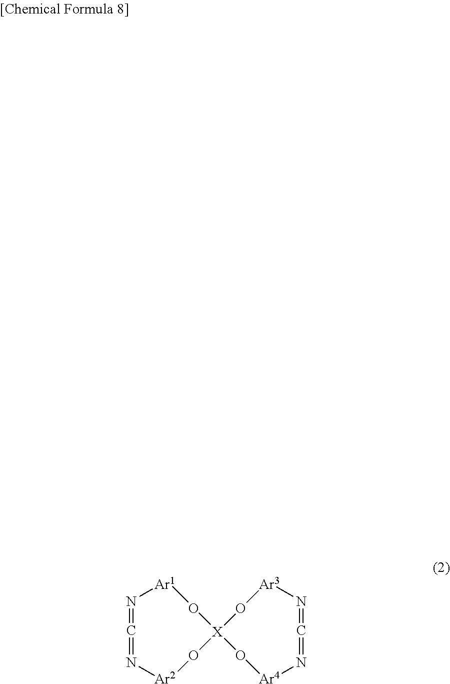

In the formula, X is a tetravalent group represented by the following formula (3). In the formula, Ar¹ to Ar⁴ are each independently an orthophenylene group or a 1,2-naphthalene-diyl group which may have a substituent. Examples of the substituent include an alkyl group having 1 to 20 carbon atoms, an aryl group having 6 to 15 carbon atoms, a halogen atom, a nitro group, an amide group, a hydroxyl group, an ester group, an ether group, an aldehyde group, and the like. Ar¹ to Ar⁴ may have a heterocyclic structure containing a heteroatom. Examples of the heteroatom include an oxygen atom, a nitrogen atom, a sulfur atom, a phosphorus atom, and the like.

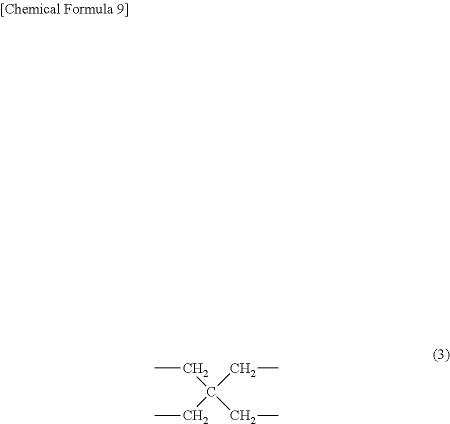

Specific example compounds of the compound represented by general formula (2) include the following compounds.

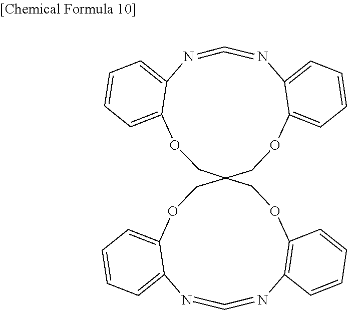

These cyclic carbodiimide compounds may be produced by methods well known in various literature, patent publications, and the like.

Examples of commercially available cyclic carbodiimide compounds include TCC-FP10M (Teijin Limited, trade name) and the like.

The content ratio of the cyclic carbodiimide compound in the resin composition is not particularly limited, and is preferably, for example, 0.05% by mass to 20% by mass of the entire resin composition, more preferably 0.1% by mass to 20% by mass, further preferably 0.2% by mass to 15% by mass, and particularly preferably 0.5% by mass to 10% by mass.

The content of the cyclic carbodiimide compound relative to 100 parts by mass of the epoxy resin is not particularly limited, and from the viewpoint of enhancing the strength of the cured product, it is preferably 1 part by mass or more, more preferably 3 parts by mass or more, further preferably 5 parts by mass or more, and particularly preferably 10 parts by mass or more.

In addition, the content of the cyclic carbodiimide compound relative to 100 parts by mass of the epoxy resin is preferably 50 parts by mass or less, more preferably 45 parts by mass or less, further preferably 40 parts by mass or less, and particularly preferably 30 parts by mass or less from the viewpoint of suppressing a decrease in hardness immediately after molding.

The ratio of the total amount of the functional group equivalent number of the entire curing agent and the imide group equivalent number of the cyclic carbodiimide compound to the epoxy group equivalent number of the epoxy resin [(functional group equivalent number of the entire curing agent+imide group equivalent number of the cyclic carbodiimide compound)/epoxy group equivalent number of the epoxy resin] is preferably 0.51 to 2.20, more preferably 0.61 to 1.50, further preferably 0.81 to 1.40, and particularly preferably 1.01 to 1.20.

### (Inorganic Filler)

The resin composition contains an inorganic filler including silica. The type of silica is not particularly limited, and may be any of fused silica, crystalline silica, and the like. The silica may be used alone or in combination of two or more types.

The average particle diameter of the silica is preferably 0.2 μm to 100 μm, and more preferably 0.5 μm to 50 μm. In the case of the average particle diameter of the silica being 0.2 μm or more, an increase in viscosity of the resin composition tends to be more suppressed. In the case of the volume average particle diameter of the silica being 100 μm or less, the fillability of the resin composition tends to be more improved.

The average particle diameter of the silica may be measured as follows. The resin composition is placed in a crucible and left at 800° C. for 4 hours to be ashed. The particle size distribution of the ash obtained using a laser diffraction/scattering particle size distribution analyzer (for example, LA920, HORIBA, Ltd.) is determined, and the average particle diameter of the silica may be obtained as the volume average particle diameter (D50) from the particle size distribution.

The specific surface area of the silica is preferably 1.3 m²/g to 10.0 m²/g, more preferably 2.0 m²/g to 8.0 m²/g, and further preferably 2.5 m²/g to 7.5 m²/g from the viewpoint of fluidity.

The BET method is mainly applied as a measurement method for the specific surface area of silica. The BET method is a gas adsorption method in which inert gas molecules such as nitrogen (N₂), argon (Ar), krypton (Kr), and the like are adsorbed onto solid particles, and the specific surface area of the solid particles is measured from the amount of adsorbed gas molecules. The measurement of specific surface area may be performed using a specific surface area pore distribution analyzer (for example, SA3100, manufactured by Beckman Coulter).

The shape of the silica is not particularly limited, and examples include spherical, elliptical, irregular, and the like. In addition, other fillers may be crushed ones.

The shape of the silica is preferably spherical from the viewpoint of improving the fluidity of the resin composition.

The inorganic filler may include other inorganic fillers other than silica. The type of other inorganic fillers is not particularly limited, and examples include inorganic materials such as glass, alumina, calcium carbonate, zirconium silicate, calcium silicate, silicon nitride, aluminum nitride, boron nitride, beryllia, zirconia, zircon, forsterite, steatite, spinel, mullite, titania, talc, clay, mica, and the like.

The shape of other inorganic fillers is not particularly limited, and examples include spherical, elliptical, irregular, and the like. In addition, other inorganic fillers may be crushed ones.

The shape of other inorganic fillers is preferably spherical from the viewpoint of improving the fluidity of the resin composition.

As the other inorganic filler, inorganic fillers having flame retardant properties may be used. Examples of inorganic fillers having flame retardant properties include aluminum hydroxide, magnesium hydroxide, composite metal hydroxides such as composite hydroxide of magnesium and zinc, and zinc borate.

Other inorganic fillers may be used singly or in combination of two or more types.

The content ratio of silica with respect to the entire inorganic filler is preferably 60% by volume or more, more preferably 65% by volume or more, and even more preferably 70% by volume or more from the viewpoint of reducing the coefficient of linear expansion.

The content ratio of the entire inorganic filler contained in the resin composition is not particularly limited. From the viewpoints of fluidity and strength, it is preferably 30% by volume to 90% by volume of the entire resin composition, more preferably 35% by volume to 80% by volume, and even more preferably 40% by volume to 70% by volume. In the case of the content ratio of the inorganic filler being 30% by volume or more of the entire resin composition, properties such as thermal expansion coefficient, thermal conductivity, and elastic modulus of the cured product tend to be further improved. In the case of the content ratio of the inorganic filler being 90% by volume or less of the entire resin composition, an increase in viscosity of the sealing resin composition is suppressed, fluidity is further improved, and moldability tends to become better.

### [Various Additives]

The resin composition may contain, in addition to the above-mentioned components, various additives such as curing accelerators, coupling agents, ion exchangers, release agents, flame retardants, colorants, stress relaxation agents, and the like exemplified below. The resin composition in the present embodiment may contain various additives well known in the technical field as necessary, in addition to the additives exemplified below.

### (Curing Accelerator)

The resin composition may contain a curing accelerator as necessary. The type of curing accelerator is not particularly limited and may be selected according to the type of epoxy resin or curing agent, desired properties of the resin composition, and the like.

Examples of the curing accelerator include diazabicycloalkenes such as 1,5-diazabicyclo[4.3.0]nonene-5 (DBN) and 1,8-diazabicyclo[5.4.0]undecene-7 (DBU); cyclic amidine compounds such as 2-methylimidazole, 2-phenylimidazole, 2-phenyl-4-methylimidazole, 2-ethyl-4-methylimidazole, and 2-heptadecylimidazole; derivatives of the cyclic amidine compounds; phenol novolac salts of the cyclic amidine compounds or derivatives thereof; compounds having intramolecular polarization formed by adding compounds having π bonds such as quinone compounds including maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, and phenyl-1,4-benzoquinone, and diazophenylmethane to these compounds; cyclic amidinium compounds such as tetraphenylborate salt of DBU, tetraphenylborate salt of DBN, tetraphenylborate salt of 2-ethyl-4-methylimidazole, and tetraphenylborate salt of N-methylmorpholine; tertiary amine compounds such as pyridine, triethylamine, triethylenediamine, benzyldimethylamine, triethanolamine, dimethylaminoethanol, and tris(dimethylaminomethyl)phenol; derivatives of the tertiary amine compounds; ammonium salt compounds such as tetra-n-butylammonium acetate, tetra-n-butylammonium phosphate, tetraethylammonium acetate, tetra-n-hexylammonium benzoate, and tetrapropylammonium hydroxide; organic phosphines such as primary phosphines including ethylphosphine and phenylphosphine, secondary phosphines including dimethylphosphine and diphenylphosphine, and tertiary phosphines including triphenylphosphine, diphenyl(p-tolyl)phosphine, tris(alkylphenyl)phosphine, tris(alkoxyphenyl)phosphine, tris(alkyl alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylarylphosphine, alkyldiarylphosphine, trinaphthylphosphine, and tris(benzyl)phosphine; phosphine compounds such as complexes of the organic phosphines with organic borons; compounds having intramolecular polarization formed by adding compounds having π bonds such as quinone compounds including maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and anthraquinone, and diazophenylmethane to the organic phosphines or the phosphine compounds; compounds having intramolecular polarization obtained through a dehydrohalogenation step after reacting the organic phosphines or the phosphine compounds with halogenated phenolic compounds such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, and 4-bromo-4′-hydroxybiphenyl; tetrasubstituted phosphonium compounds such as tetrasubstituted phosphonium including tetraphenylphosphonium, tetraphenylborate salts of tetrasubstituted phosphonium such as tetraphenylphosphonium tetra-p-tolylborate, and salts of tetrasubstituted phosphonium with phenolic compounds; salts of tetraalkylphosphonium with partial hydrolysates of aromatic carboxylic anhydrides; phosphobetaine compounds; adducts of phosphonium compounds with silane compounds; and the like.

The curing accelerator may be used alone or in combination of two or more types.

Among these, particularly suitable curing accelerators include triphenylphosphine, adducts of triphenylphosphine and quinone compounds, adducts of tributylphosphine and quinone compounds, adducts of tri-p-tolylphosphine and quinone compounds, and the like.

In the case of the resin composition containing a curing accelerator, the amount thereof is preferably 0.1 parts by mass to 30 parts by mass, more preferably 1 part by mass to 15 parts by mass, relative to 100 parts by mass of the resin component (total amount of epoxy resin and curing agent). In the case of the amount of the curing accelerator being 0.1 parts by mass or more relative to 100 parts by mass of the resin component, there is a tendency to cure favorably in a short time. In the case of the amount of the curing accelerator being 30 parts by mass or less relative to 100 parts by mass of the resin component, there is a tendency that the curing rate is not too fast and a favorable molded product may be obtained.

### (Coupling Agent)

The resin composition may contain a coupling agent. From the viewpoint of enhancing the adhesion between the resin component and the inorganic filler, the resin composition preferably contains a coupling agent. Examples of the coupling agent include known coupling agents such as silane-based compounds such as epoxysilane, mercaptosilane, aminosilane, alkylsilane, ureidosilane, vinylsilane, and disilazane, titanium-based compounds, aluminum chelate-based compounds, and aluminum/zirconium-based compounds.

In the case of the resin composition containing a coupling agent, the amount of the coupling agent is preferably 0.05 parts by mass to 10 parts by mass, more preferably 0.1 parts by mass to 5 parts by mass, relative to 100 parts by mass of the inorganic filler. In the case of the amount of the coupling agent being 0.05 parts by mass or more relative to 100 parts by mass of the inorganic filler, there is a tendency that the adhesion with the frame is further improved. In the case of the amount of the coupling agent being 5 parts by mass or less relative to 100 parts by mass of the inorganic filler, there is a tendency that the moldability of the package is further improved.

### (Ion Exchanger)

The resin composition may contain an ion exchanger. The resin composition preferably contains an ion exchanger from the viewpoint of improving the moisture resistance and high-temperature storage characteristics of an electronic component device including electronic components to be sealed. The ion exchanger is not particularly limited, and conventionally known ones may be used. Specifically, hydrotalcite compounds, and hydrous oxides of at least one element selected from the group consisting of magnesium, aluminum, titanium, zirconium, and bismuth may be raised. The ion exchanger may be used singly or in combination of two or more kinds. Among these, hydrotalcite represented by the following general formula (A) is preferred.

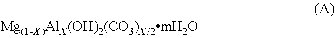

(0<X≤0.5, m is a positive number)

In the case of the resin composition containing an ion exchanger, the content thereof is not particularly limited as long as it is a sufficient amount to capture ions such as halogen ions. For example, the content of the ion exchanger is preferably 0.1 parts by mass to 30 parts by mass, more preferably 1 part by mass to 10 parts by mass, relative to 100 parts by mass of the resin component (total amount of the epoxy resin and the curing agent).

### (Release Agent)

The resin composition may contain a release agent from the viewpoint of obtaining good releasability from a mold during molding. The release agent is not particularly limited, and conventionally known ones may be used. Specifically, carnauba wax, higher fatty acids such as montanic acid and stearic acid, higher fatty acid metal salts, ester-based waxes such as montanic acid ester, polyolefin-based waxes such as oxidized polyethylene and non-oxidized polyethylene may be raised. The release agent may be used singly or in combination of two or more kinds.

In the case of the resin composition containing a release agent, the amount thereof is preferably 0.01 parts by mass to 10 parts by mass, more preferably 0.1 parts by mass to 5 parts by mass, relative to 100 parts by mass of the resin component (total amount of the epoxy resin and the curing agent). In the case of the amount of the release agent being 0.01 parts by mass or more relative to 100 parts by mass of the resin component, sufficient releasability tends to be obtained. In the case of 10 parts by mass or less, better adhesiveness tends to be obtained.

### (Flame Retardant)

The resin composition may contain a flame retardant. The flame retardant is not particularly limited, and conventionally known ones may be used. Specifically, organic or inorganic compounds containing halogen atoms, antimony atoms, nitrogen atoms or phosphorus atoms, metal hydroxides, and the like may be raised. The flame retardant may be used singly or in combination of two or more kinds.

In the case of the resin composition containing a flame retardant, the amount thereof is not particularly limited as long as it is a sufficient amount to obtain a desired flame retardant effect. For example, it is preferably 1 part by mass to 30 parts by mass, more preferably 2 parts by mass to 20 parts by mass, relative to 100 parts by mass of the resin component (total amount of the epoxy resin and the curing agent).

### (Colorant)

The resin composition may contain a colorant. As the colorant, known colorants such as carbon black, organic dyes, organic pigments, titanium oxide, red lead, and red iron oxide may be raised. The content of the colorant may be appropriately selected according to the purpose and the like. The colorant may be used singly or in combination of two or more kinds.

### (Stress Relaxation Agent)

The resin composition may contain a stress relaxation agent. By containing a stress relaxation agent, warping deformation of the package and occurrence of package cracks may be further reduced. As the stress relaxation agent, generally used known stress relaxation agents (flexibilizers) may be raised. Specifically, thermoplastic elastomers such as silicone-based, styrene-based, olefin-based, urethane-based, polyester-based, polyether-based, polyamide-based, and polybutadiene-based ones, rubber particles such as NR (natural rubber), NBR (acrylonitrile-butadiene rubber), acrylic rubber, urethane rubber, and silicone powder, and rubber particles having a core-shell structure such as methyl methacrylate-styrene-butadiene copolymer (MBS), methyl methacrylate-silicone copolymer, and methyl methacrylate-butyl acrylate copolymer may be raised. The stress relaxation agent may be used singly or in combination of two or more kinds.

Among the stress relaxation agents, silicone-based stress relaxation agents are preferable. As the silicone-based stress relaxation agent, those having epoxy groups, those having amino groups, those obtained by polyether-modifying these, and the like may be raised, and silicone compounds such as silicone compounds having epoxy groups and polyether-based silicone compounds are more preferable.

In the case of the resin composition containing a stress relaxation agent, the amount thereof is preferably 1 part by mass to 30 parts by mass, more preferably 2 parts by mass to 20 parts by mass, relative to 100 parts by mass of the resin component (total amount of the epoxy resin and the curing agent), for example.

The resin composition preferably has a content ratio of solvent of 5% by mass or less, more preferably 1% by mass or less, further preferably 0.5% by mass or less, and particularly preferably substantially contains no solvent (0% by mass).

### (Method for Preparing Resin Composition)

The method for preparing the resin composition is not particularly limited. As a general technique, a method may be raised in which components in predetermined blending amounts are sufficiently mixed by a mixer or the like, then melt-kneaded by a mixing roll, extruder, or the like, cooled, and pulverized. More specifically, for example, a method may be raised in which predetermined amounts of the above-described components are stirred and mixed, kneaded with a kneader, roll, extruder, or the like preheated to 70° C. to 140° C., cooled, and pulverized.

The resin composition in the present embodiment is preferably solid under normal temperature and normal pressure (for example, 25° C., under atmospheric pressure). The shape in the case of the resin composition being solid is not particularly limited, and powder form, granular form, tablet form, and the like may be raised. In the case of the resin composition being in tablet form, it is preferable from the viewpoint of handleability that the dimensions and mass be such dimensions and mass that match the molding conditions of the package.

### (Properties of Resin Composition)

### —Relative Permittivity—

The relative permittivity at 5 GHz of a cured product obtained by molding the resin composition by compression molding under conditions of a mold temperature of 175° C., molding pressure of 6.9 MPa, and curing time of 600 seconds, and performing post-curing at 175° C. for 6 hours is, for example, 3.4 to 4.0, and preferably 3.4 to 3.7.

The relative permittivity at 10 GHz of the cured product is, for example, 3.3 to 4.0, preferably 3.3 to 3.7, more preferably 3.3 to 3.5, and may be 3.38 or less.

The measurement of the relative permittivity is performed using a dielectric constant measuring device (for example, Agilent Technologies, product name “Network Analyzer N5227A”) at a temperature of 25±3° C.

### —Dielectric Loss Tangent—

The dielectric loss tangent at 5 GHz of a cured product obtained by molding the resin composition by compression molding under conditions of a mold temperature of 175° C., molding pressure of 6.9 MPa, and curing time of 600 seconds, and performing post-curing at 175° C. for 6 hours is, for example, 0.01 or less, preferably 0.005 or less from the viewpoint of reducing transmission loss, more preferably 0.003 or less, and even more preferably 0.0021 or less. The lower limit of the dielectric loss tangent at 5 GHz of the cured product is not particularly limited, and is, for example, 0.0015 or more.

The dielectric loss tangent at 10 GHz of the cured product is, for example, 0.0020 to 0.0030, preferably 0.0020 to 0.0027, and more preferably 0.0020 to 0.0025.

The measurement of the dielectric loss tangent is performed using a dielectric constant measuring device (for example, Agilent Technologies, product name “Network Analyzer N5227A”) at a temperature of 25±3° C.

### —Flexural Elastic Modulus—

The elastic modulus of a cured product obtained by molding the resin composition using a transfer molding machine under conditions of a mold temperature of 175° C., molding pressure of 6.9 MPa, and curing time of 300 seconds is preferably 15 GPa or more, more preferably 17 GPa or more, and even more preferably 19 GPa or more.

The upper limit of the elastic modulus is not particularly limited, but may be 25 GPa or less, or may be 30 GPa or less.

For the cured product, a three-point bending test in accordance with JIS-K-7171 (2016) is performed at 25° C. using a Tensilon universal material testing machine (Instron Corporation, product name “Instron 5948”), and the flexural elastic modulus El (GPa) of the test specimen at 25° C. is obtained.

### —Flexural Strength—

The flexural strength of a cured product obtained by preparing a test specimen having a shape of 4.0 mm×10.0 mm×80 mm from the resin composition using a transfer molding machine under conditions of a mold temperature of 175° C., molding pressure of 6.9 MPa, and curing time of 300 seconds, and performing post-curing at 175° C. for 6 hours is preferably 110 MPa or more, more preferably 120 MPa or more, and even more preferably 125 MPa or more.

The upper limit of the flexural strength is not particularly limited, but may be 140 MPa or less, may be 135 MPa or less, or may be 130 MPa or less.

The flexural strength is obtained by performing a bending test on the cured product using a Tensilon universal material testing machine (for example, Instron Corporation, product name “Instron 5948”) under conditions of a temperature of 25° C., creating a flexural stress-displacement curve from the following formula (A), and taking the maximum stress as the flexural strength (MPa).

$$σ = 3 FL / 2 {bh}^{2} \cdot \cdot \cdot \qquad Formula ( A )$$

σ: flexural stress (MPa)
F: flexural load (N)
L: distance between fulcrums (mm)
b: test specimen width (mm)
h: test specimen thickness (mm)

### —Spiral Flow—

In a case where the resin composition is molded using a spiral flow measurement mold conforming to EMMI-1-66 under conditions of a mold temperature of 175° C., a molding pressure of 6.9 MPa, and a curing time of 120 seconds, the flow distance (hereinafter also referred to as “spiral flow”) is preferably 80 cm or more, more preferably 100 cm or more, and even more preferably 110 cm or more. The upper limit of the spiral flow is not particularly limited, and may be, for example, 200 cm or less.

The gel time of the resin composition at 175° C. is preferably 30 seconds to 90 seconds, and more preferably 40 seconds to 60 seconds.

The measurement of gel time at 175° C. is performed as follows. Specifically, measurement using a curastometer (for example, manufactured by JSR Trading Co., Ltd.) is performed at a temperature of 175° C. on 3 g of a sample of the resin composition, and the time until the rise of the torque curve is measured as the gel time (sec).

### (Applications of Resin Composition)

The resin composition in the present embodiment may be applied to, for example, electronic component devices described below, particularly to the manufacture of high-frequency devices.

### <Electronic Component Device>

An electronic component device according to one embodiment of the disclosure includes a support member, an electronic component disposed on the support member, and a cured product of the aforementioned resin composition that seals the electronic component.

Examples of electronic component devices include those in which an electronic component region obtained by mounting electronic components (active elements such as semiconductor chips, transistors, diodes, and thyristors; passive elements such as capacitors, resistors, and coils; antennas, etc.) on support members such as lead frames, wired tape carriers, wiring boards, glass, silicon wafers, and organic substrates is sealed with a resin composition (for example, high-frequency devices).

The type of the support member is not particularly limited, and support members generally used in the manufacture of electronic component devices may be used.

In the electronic component device of the present embodiment, other electronic components may be disposed on the surface of the support member opposite to the surface on which the electronic components are disposed, as necessary. The other electronic components may be sealed with the aforementioned resin composition, may be sealed with other resin compositions, or may not be sealed.

### (Method for Manufacturing Electronic Component Device)

The method for manufacturing an electronic component device according to the present embodiment includes a step of disposing an electronic component on a support member, and a step of sealing the electronic component with the aforementioned resin composition.

The method for performing each of the above steps is not particularly limited, and may be performed by general techniques. In addition, the types of support member and electronic component used in manufacturing the electronic component device are not particularly limited, and support members and electronic components generally used in manufacturing electronic component devices may be used.

Examples of methods for sealing electronic components using the aforementioned resin composition include low-pressure transfer molding, injection molding, compression molding, and the like. Among these, low-pressure transfer molding is common.

### EXAMPLES

Hereinafter, the above embodiment will be specifically described by Examples, but the scope of the above embodiment is not limited to these Examples.

### <Preparation of Resin Composition>

The components shown below were mixed in the blending ratios (parts by mass) shown in Table 1 to prepare resin compositions of Examples and Comparative Examples. These resin compositions were solid under normal temperature and pressure.

In addition, the content ratio of inorganic filler relative to the entire resin composition (“Vf” in the table (% by volume)) was also shown in Table 1.

Furthermore, the “equivalent number ratio” expressed by “(equivalent number of ester groups of active ester compound+equivalent number of imide groups of carbodiimide groups)/equivalent number of epoxy groups of epoxy resin” is also shown in Table 1.
Epoxy resin 1: orthocresol novolac-type epoxy resin, epoxy equivalent 200 g/eq
Epoxy resin 2: biphenyl-type epoxy resin, epoxy equivalent 192 g/eq
Curing agent: active ester compound, DIC Corporation, product name “EXB-8”
Cyclic carbodiimide compound (imide equivalent 256 g/eq, specific example compound listed as the general formula (2) above)
Curing accelerator: adduct of tributylphosphine and 1,4-benzoquinone
Coupling agent: N-phenyl-3-aminopropyltrimethoxysilane
Release agent: montanic acid ester wax (Clariant Japan K.K.)
Colorant: carbon black (Mitsubishi Chemical Corporation)
Inorganic filler 1: silica particles, average particle diameter: 3 μm, specific surface area: 3.0 m²/g
Inorganic filler 2: silica particles, average particle diameter: 0.5 μm, specific surface area: 6.6 m²/g

The volume average particle diameter of each of the above inorganic fillers is a value obtained by the following measurement.

Specifically, first, the inorganic filler was added to a dispersion medium (water) in a range of 0.01% by mass to 0.1% by mass, and dispersed for 5 minutes using a bath-type ultrasonic cleaner.

5 ml of the obtained dispersion liquid was injected into a cell, and the particle size distribution was measured at 25° C. using a laser diffraction/scattering particle size distribution analyzer (Horiba, Ltd., LA920).

The particle diameter at a cumulative value of 50% (volume-based) in the obtained particle size distribution was taken as the volume average particle diameter.

### <Evaluation of Resin Composition>

### (Relative Permittivity and Dielectric Loss Tangent)

The resin composition was charged into a vacuum hand press machine, molded under conditions of a mold temperature of 175° C., molding pressure of 6.9 MPa, and curing time of 600 seconds, and post-curing was performed at 175° C. for 6 hours to obtain a cured product having a length of 50 mm, width of 0.5 mm, and thickness of 0.5 mm. Using this cured product as a test specimen, the relative permittivity (Dk) and dielectric loss tangent (Df) at 5 GHz and 10 GHz were measured at a temperature of 25±3° C. using a dielectric constant measuring device (Agilent Technologies, product name “Network Analyzer N5227A”). The results are shown in Table 1.

### (Fluidity: Spiral Flow)

Using a spiral flow measurement mold according to EMMI-1-66, the resin composition was molded under conditions of a mold temperature of 175° C., molding pressure of 6.9 MPa, and curing time of 120 seconds, and the flow distance (cm) was obtained. The results are shown in Table 1.

### (Gel Time)

For 3 g of the resin composition, measurement was performed at a temperature of 175° C. using a curastometer from JSR Trading Co., Ltd., and the time until the rise of the torque curve was taken as the gel time (seconds). The results are shown in Table 1.

### (Flexural Elastic Modulus)

The resin composition was molded in a transfer molding machine under conditions of a mold temperature of 175° C., a molding pressure of 6.9 MPa, and a curing time of 300 seconds to prepare a test specimen measuring 4.0 mm×10.0 mm×80 mm.

For the obtained cured product, a three-point bending test in accordance with JIS-K-7171 (2016) was performed at 25° C. using a Tensilon universal material testing machine (Instron Corporation, product name “Instron 5948”), and the flexural elastic modulus E1 (GPa) of the test specimen at 25° C. was obtained.

The flexural elastic modulus was obtained by the following formula. In the following formula, E is the flexural elastic modulus (GPa), P is the load cell value (N), y is the displacement amount (mm), l is the span=64 mm, w is the test specimen width=12.7 mm, and h is the test specimen thickness=4 mm.

$$E = \frac{{l}^{3}}{4 {wh}^{3}} \frac{Δ P}{Δ y} \times 1000 \qquad [ Equation 1 ]$$

### (Flexural Strength)

The resin composition was charged into a transfer molding machine and molded into a rectangular parallelepiped of 4.0 mm×10.0 mm×80 mm at a mold temperature of 175° C., molding pressure of 6.9 MPa, and curing time of 90 seconds, followed by post-curing at 175° C. for 6 hours to prepare test specimens for flexural strength evaluation. Using these test specimens, a bending test was performed with a Tensilon universal material testing machine (Instron 5948, Instron Corporation) under conditions of a distance between fulcrums of 64 mm, crosshead speed of 10 mm/mmn, and temperature of 25° C. Using the measured results, a flexural stress-displacement curve was created from the above formula (A), and the maximum stress was taken as the flexural strength (MPa). The results are shown in Table 1.

TABLE 1

| | | Comparative | | |
|---|---|---|---|---|
| | | Example 1 | Example 1 | Example 2 |
| Epoxy resin | 1 | 75 | 75 | 75 |
| | 2 | 25 | 25 | 25 |
| Curing agent | | 108 | 108 | 108 |
| Cyclic carbodiimide compound | | | 10 | 20 |
| Curing accelerator | | 3.5 | 3.5 | 3.5 |
| Coupling agent | | 5 | 5 | 5 |
| Release agent | | 1 | 1 | 1 |
| Colorant | | 2.6 | 2.6 | 2.6 |
| Inorganic filler amount (Vf) (% by | | 72 | 72 | 72 |
| volume) | | | | |
| Inorganic filler | 1 | 871 | 910 | 949 |
| | 2 | 218 | 228 | 237 |
| Equivalent number ratio | | 1 | 1.08 | 1.15 |
| Gel time (seconds) | | 52 | 52 | 59 |
| Spiral flow (cm) | | 180 | 178 | 175 |
| Dk | 5 GHz | 3.49 | 3.48 | 3.45 |
| | 10 GHz | 3.39 | 3.37 | 3.37 |
| Df | 5 GHz | 0.00221 | 0.00201 | 0.00196 |
| | 10 GHz | 0.00261 | 0.00238 | 0.00230 |

| | | | |
|---|---|---|---|
| Elastic modulus (GPa) | 20.8 | 20.6 | 20.9 |
| Flexural strength (MPa) | 125 | 128 | 135 |

As shown in Table 1, the cured products obtained from the resin compositions of Examples 1 and 2 had reduced dielectric loss tangent and significantly improved flexural strength compared to the cured product obtained from the resin composition of Comparative Example 1.

The disclosure of Japanese Patent Application No. 2023-119484 is incorporated herein by reference in its entirety. All documents, patent applications, and technical standards described in this specification are incorporated herein by reference to the same extent as if each individual document, patent application, and technical standard were specifically and individually indicated to be incorporated by reference.

1. A resin composition, comprising an epoxy resin, an active ester compound as a curing agent, an inorganic filler containing silica, and a cyclic carbodiimide compound.

2. The resin composition according to claim 1, wherein a content of the cyclic carbodiimide compound is 1 part by mass or more with respect to 100 parts by mass of the epoxy resin.

3. The resin composition according to claim 1, wherein a content of the cyclic carbodiimide compound is 50 parts by mass or less with respect to 100 parts by mass of the epoxy resin.

4. The resin composition according to claim 1, wherein a ratio of a total amount of a functional group equivalent number of the entire curing agent and an imide group equivalent number of the cyclic carbodiimide compound to an epoxy group equivalent number of the epoxy resin [(functional group equivalent number of entire curing agent+imide group equivalent number of carbodiimide compound)/epoxy group equivalent number of epoxy resin] is 0.51 to 2.20.

5. The resin composition according to claim 1, further comprising at least one selected from a group consisting of a curing accelerator, a coupling agent, an ion exchanger, a release agent, a flame retardant, a colorant, and a stress relaxation agent.

6. An electronic component device, comprising:
a support member;
an electronic component disposed on the support member; and
a cured product of the resin composition according to claim 1 that seals the electronic component.

7. The resin composition according to claim 2, wherein the content of the cyclic carbodiimide compound is 50 parts by mass or less with respect to 100 parts by mass of the epoxy resin.

8. The resin composition according to claim 2, wherein a ratio of a total amount of a functional group equivalent number of the entire curing agent and an imide group equivalent number of the cyclic carbodiimide compound to an epoxy group equivalent number of the epoxy resin [(functional group equivalent number of entire curing agent+imide group equivalent number of carbodiimide compound)/epoxy group equivalent number of epoxy resin] is 0.51 to 2.20.

9. The resin composition according to claim 2, further comprising at least one selected from a group consisting of a curing accelerator, a coupling agent, an ion exchanger, a release agent, a flame retardant, a colorant, and a stress relaxation agent.

10. An electronic component device, comprising:
a support member;
an electronic component disposed on the support member; and
a cured product of the resin composition according to claim 2 that seals the electronic component.
